(19) United States
(12) Patent Application Publication
(10) Pub. No.: US 2022/0359972 A1
(43) Pub. Date: Nov. 10, 2022

(54) SPACER AND CONNECTION SYSTEM FOR BASE STATION ANTENNA

(71) Applicant: CommScope Technologies LLC, Hickory, NC (US)

(72) Inventor: Bin Ai, Suzhou (CN)

(21) Appl. No.: 17/719,812

(22) Filed: Apr. 13, 2022

(30) Foreign Application Priority Data
May 7, 2021 (CN) 202110492978.4

(51) Int. Cl. H01Q 1/12; H01Q 1/24; H01Q 1/22

(52) U.S. Cl. CPC H01Q 1/1228; H01Q 1/246; H01Q 1/2258

(57) ABSTRACT

The present disclosure relates to a spacer configured to space a first member apart from a second member, and the spacer includes a support component and a spacer component. The support component has a body, which has a support surface for the first member to be put on, and the support component further has a first hook element separated from the support surface by a first distance and a second hook element separated from the support surface by a second distance greater than the first distance. The spacer component is used to be placed between the first member and the second member and to space the first member apart from the second member, and the spacer component can be snap-fitted with the first hook element or the second hook element relational to the thickness of the first member. The present disclosure further relates to a connection system including the spacer for a base station antenna. The spacer is advantageous in cost, compact in structure, and easy to install.

### RELATED APPLICATION

The present application claims priority from and the benefit of Chinese Patent Application No. 202110492978.4, filed May 7, 2021, the disclosure of which is hereby incorporated herein by reference in full.

### FIELD OF THE INVENTION

The present disclosure relates to a spacer for separating at least two members, and the spacer may be used, for example, in a base station antenna. The present disclosure further relates to a connection system including such a spacer for a base station antenna.

### BACKGROUND OF THE INVENTION

In a communication system, such as a base station antenna, it is usually necessary to space at least two members apart from each other by a predetermined distance. For example, two metal plates or two printed circuit boards can be spaced apart and electrically isolated from each other by a spacer made of dielectric. The spacer can be made of plastic or other suitable materials. In a base station antenna, miniaturization of the spacer, minimization of openings for the spacer in two members, and ease of installation of the spacer are desirable.

### SUMMARY OF THE INVENTION

The objective of the present disclosure is to provide a spacer and a connection system including the spacer for a base station antenna, where the spacer is compact in structure, advantageous in cost, and easy to install.

A first aspect of the present disclosure relates to a spacer configured to space a first member apart from a second member, the spacer including:

a support component, which includes a body having a support surface for the first member to be put on, the support component further includes a first hook element separated from the support surface by a first distance and a second hook element separated from the support surface by a second distance greater than the first distance; and

a spacer component, which is configured to be placed between the first member and the second member and to space the first member apart from the second member, the spacer component being capable of being snap-fitted with the first hook element or the second hook element relational to the thickness of the first member.

The spacer may be produced from plastic or other suitable materials at a cost advantage. During installation, the support component can be held on the first member through snap fit with the spacer component. When, in addition to the snap fit between the support component and the spacer component, an additional fastening element such as a screw is required for fastening, it is possible to simply manipulate the fastening element without the need of manipulating the support component during the fastening.

In some embodiments, the support component may have a pair of first arms protruding from the support surface, and each first arm may have the first hook element and the second hook element.

In some embodiments, each first arm may have a first hook element in a center on a width of the first arm and two second hook elements preferably located on a free end of the first arm and preferably on both sides of the first hook element on the width of the first arm.

In some embodiments, the support component may have a pair of first arms protruding from the support surface and a pair of second arms protruding from the support surface. Each first arm may have the second hook element, and each second arm may have the first hook element. The first hook element and the second hook element may be provided on free ends of the corresponding arms to make the height of the arms as small as possible.

In some embodiments, the support surface is substantially in a rectangular shape. The first arm may be provided on a short side of the rectangular shape. The second arm may be provided on a long side of the rectangular shape, for example, centrally provided on the long side.

In some embodiments, the first hook elements on the pair of the first arms face each other and/or the second hook elements on the pair of the first arms face each other.

In some embodiments, the second hook elements on the pair of the first arms face each other and/or the first hook elements on the pair of the second arms face each other.

In some embodiments, all the arms may be distributed and arranged with an angular separation of 90°.

In some embodiments, the spacer component may have a protruding protrusion on a first side facing the support component, and the support component may have a recess for receiving the protrusion. The protrusion and the recess can prevent the spacer component and the support component from rotating relative to each other during engagement.

In some embodiments, the support component may have at least one, preferably one, recess on an inner side of each first arm in the body of the support component. The spacer component has at least one, preferably two protruding protrusions on the first side facing the support component corresponding to each recess, and the protrusions and the recesses can prevent the spacer component and the support component from rotating relative to each other during engagement.

In some embodiments, the spacer component may have a sunken step on a second side facing away from the support component, and the step may be used for snap fit of the spacer component with the first hook element or the second hook element.

In some embodiments, the spacer component may have a pair of sunken steps on the second side facing away from the support component, and each step may be used for the snap fit of the spacer component with the first hook element or the second hook element of one of the first arms.

In some embodiments, the spacer may include a fastening element. The support component and the spacer component have aligned mounting holes, and the mounting holes are used to receive the fastening element. The fastening element may be, for example, a screw, a rivet, or a push-in rivet.

In some embodiments, the spacer component may have a first projection surrounding the mounting hole of the spacer component on the first side facing the support component, where the first projection is used to be inserted into a mounting hole of the first member.

In some embodiments, the first projection may have a contour complementary to that of the mounting hole of the first member, for example, a circular, oval, or square contour.

In some embodiments, the spacer component may have a second projection surrounding the mounting hole of the spacer component on the second side facing away from the support component, where the second projection is used to be inserted into a mounting hole of the second member.

In some embodiments, the second projection may have a contour complementary to that of the mounting hole of the second member, for example, a circular, oval, or square contour.

In some embodiments, the spacer may be configured to be used for a base station antenna.

In some embodiments, the first member and the second member may be plate elements of a base station antenna, for example, at least one of a reflector, a base plate, and a printed circuit board.

A second aspect of the present disclosure relates to a connection system for a base station antenna, including a first member and a second member for a base station antenna, and the spacer according to the first aspect of the present disclosure, the first member and the second member respectively including at least one mounting hole penetrated by at least one of the support component and the spacer component of the spacer, the first member being put on the support surface of the support component of the spacer, the spacer component of the spacer being placed between the first member and the second member and spacing the first member apart from the second member, and the spacer component being snap-fitted with the first hook element or the second hook element of the support component of the spacer relational to the thickness of the first member.

In some embodiments, the first member may have a central mounting hole and two lateral mounting holes on both sides of the central mounting hole.

In some embodiments, the second member may have a central mounting hole and two lateral mounting holes on both sides of the central mounting hole.

It should be pointed out here that the above-mentioned technical features, the technical features to be mentioned below and the technical features shown separately in the drawings can be arbitrarily combined with each other as long as the combined technical features are not contradictory. All technically feasible feature combinations are technical contents included in the Specification.

### BRIEF DESCRIPTION OF FIGURES

Exemplary embodiments the present disclosure are described below with reference to the drawings. Of them:

FIGS. 1A to 1C. are three different perspective views of a support component of a spacer according to an embodiment of the present disclosure.

FIGS. 2A and 2B are two different perspective views of a spacer component of the spacer.

FIG. 3 is a partial cross-sectional view of a connection system including the spacer according to an embodiment of the present disclosure.

FIG. 4A is a partial plan view of a first member of the connection system.

FIG. 4B is a partial plan view of a second member of the connection system.

FIGS. 5A and 5B are different perspective views of the support component of the spacer according to another embodiment of the present disclosure.

### DETAILED DESCRIPTION OF SPECIFIC EMBODIMENTS

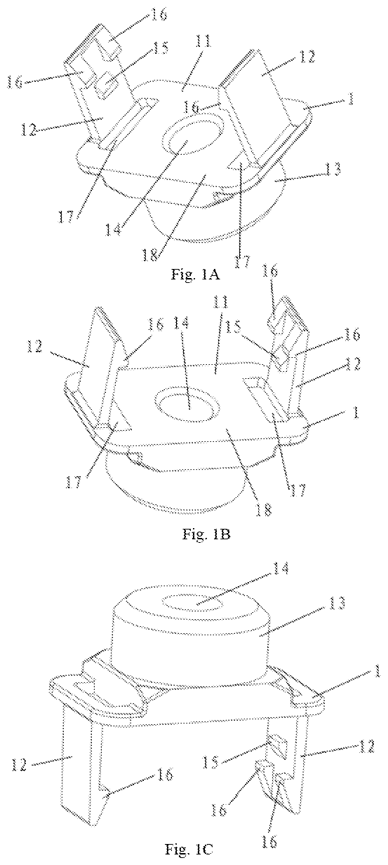

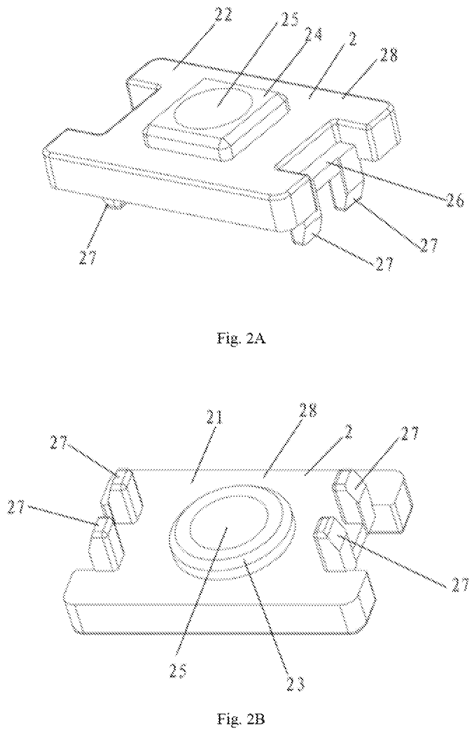

A spacer according to an embodiment of the present disclosure may mainly include a support component 1 and a spacer component 2. The support component 1 is depicted in three perspective views in FIGS. 1A to 1C, and the spacer component 2 is depicted in two perspective views in FIGS. 2A and 2B. The spacer may be used especially in base station antennas, for example, for two plate elements, such as reflectors, printed circuit boards, base plates and the like, to be spaced apart in a base station antenna. The plate element may be flat or curved. The support component 1 and the spacer component 2 may be made by injection molding.

The support component 1 may have a body 18, and the body may have a support surface 11. The support surface 11 may be a flat continuous surface as shown in FIGS. 1A to 1C, or may be an imaginary support surface composed of at least three discrete supporting points now shown. The support component 1 may have a pair of first arms 12 protruding from the support surface 11. Each first arm 12 may have a first hook element 15 separated from the support surface 11 by a first distance and two second hook elements 16 separated from the support surface 11 by a second distance greater than the first distance. For example, the first distance may be approximately half of the second distance. On each first arm 12, the first hook element 15 may be centrally arranged on a width of the first arm 12, and the two second hook elements 16 may be located on a free end of the first arm 12 and on both sides of the first hook element 15 on the width of the first arm 12. In other words, the first hook elements 15 are laterally spaced from the second hook element 16, which may facilitate manufacturing if the support component 1 is to be formed by injection molding. The support component 1 may have a column-shaped body 13 on a side of the body 18 opposite to the support surface 11. As a result, the support component 1 can have an increased thickness, and a mounting hole 14 with an increased length for receiving a fastening element can be made in the support component 1. The mounting hole 14 may be, for example, a threaded hole with an internal thread for receiving a screw. The mounting hole 14 may be a through hole or a blind hole. The support component 1 may have a recess 17 in the body 18 on an inner side of each first arm 12, and the recess may be a slot-shaped through hole, for example.

The spacer component 2 may have a planar body 28, especially a substantially rectangular body. The thickness of the body 28 may determine a predetermined distance between two members separated by the spacer. The spacer component 2 may have a protruding protrusion 27 on a first side 21 facing the support component 1. As exemplarily shown in FIGS. 2A and 2B, the spacer component 2 has two protruding protrusions 27 on the first side 21 corresponding to each recess 17 of the support component 1. The protrusions 27 of the spacer component 2 and the recesses 17 of the support component 1 can prevent the spacer component 2 and the support component 1 from rotating relative to each other during engagement. The protrusions 27 and the recesses 17 may facilitate positioning the spacer component 2 relative to the support component 1. The recesses 17 allow the spacer component 2 to move relative to the support component 1 so that the protrusions 27 can enter the support component 1. The spacer component 2 may have a pair of sunken steps 26 on a second side 22 facing away from the support component 1. Each step 26 may be used for snap-fitting of the spacer component 2 with the first hook element 15 or the second hook element 16 of one of the first arms 12. Advantageously, the protrusions 27 may be provided in an area of the corresponding step 26. The spacer component 2 may have a mounting hole 25 penetrating the body 28, and the mounting hole 25 is used to receive a fastening element. The two mounting holes 14 and 25 may be aligned to receive the fastening element. The spacer component 2 may have a first projection 23 surrounding the mounting hole 25 on the first side 21 facing the support component 1. The spacer component 2 may have a second projection 24 surrounding the mounting hole 25 on the second side 22 facing away from the support component 1. The functions of the first projection 23 and the second projection 24 will be described in more detail below with reference to FIG. 3.

FIG. 3 is a partial cross-sectional view of a connection system including the spacer according to an embodiment of the present disclosure. The connection system may include a first member 3 and a second member 4. The two members may be, for example, a reflector and a printed circuit board, or two printed circuit boards.

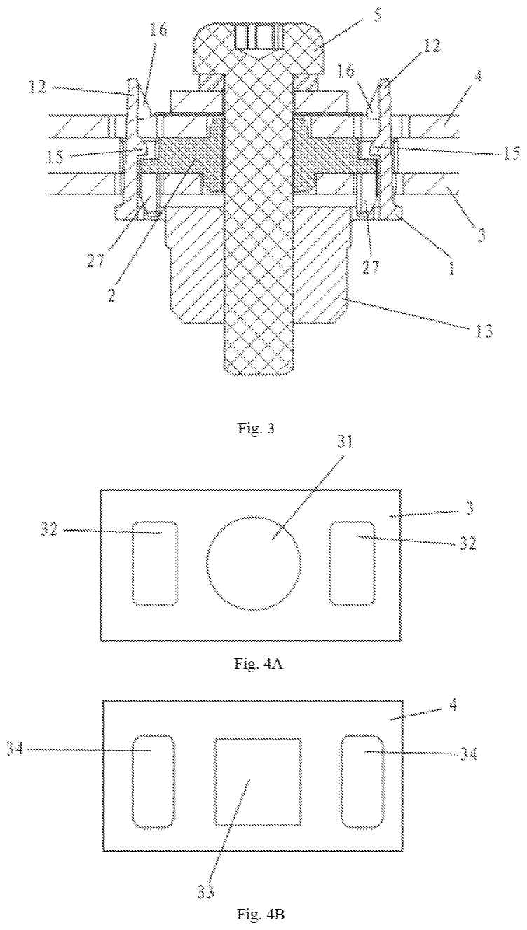

In the connection system shown in FIG. 3, the first member 3 is positioned on the support surface 11 of the support component 1, and the two first arms 12 of the support component 1 pass through two lateral mounting holes 32 of the first member 3 and two lateral mounting holes 34 of the second member 4. The spacer component 2 is placed between the first member 3 and the second member 4 and spaces the first member 3 apart from the second member 4, where the thickness of the body 28 of the spacer component 2 may determine a predetermined distance between the two members. A gasket or the like may be added when necessary, so that the distance can be adjusted or increased according to actual needs. The protrusions 27 of the spacer component 2 may be inserted into the recesses 1 of the support component 1 through the mounting holes 32 of the first member 3. The first projection 23 of the spacer component 2 may be inserted into the mounting hole 31 in the center of the first member 3. The first projection 23 and the mounting hole 31 may have complementary contours. In the embodiment shown in FIG. 4A, the first projection 23 and the mounting hole 31 may have circular contours. The second projection 24 of the spacer component 2 may be inserted into the mounting hole 33 in the center of the second member 4. The second projection 24 and the mounting hole 33 may have complementary contours. In the embodiment shown in FIG. 4B, the second projection 24 and the mounting hole 33 may have square contours.

In the embodiment shown in FIG. 3, the first member 3 has a first thickness, which makes the first hook element 15 snap-fitted with the step 26. Although the snap fit is loose, it is sufficient to hold the support component 1 on the first member 3 without accidentally disengaging. This is advantageous for installing a fastening element 5, which is exemplarily configured as a screw. When the first member 3 has an increased second thickness compared with the situation shown in FIG. 3 and the second thickness makes the step 26 pass over the first hook element 15, the step 26 can form a snap-fit with the second hook element 16 and the snap-fit is still sufficient to hold the support component 1 on the first member 3 even in the case of a loose connection.

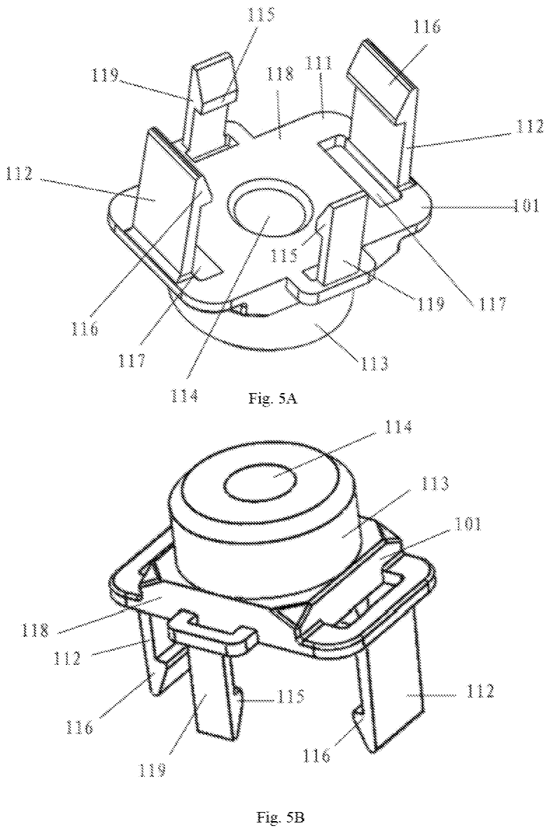

FIGS. 5A and 5B are two different perspective views of a support component 101 of a spacer according to another embodiment of the present disclosure. The spacer component of the spacer may be configured the same or substantially the same as the spacer component 2 shown in FIGS. 2A and 2B. In FIGS. 5A and 5B, the reference numerals of comparable constituent parts of the support component are increased by 100 as compared with those in FIGS. 2A and 2B. The support component 101 may have a body 118, and the body may have a support surface 111. The support component 101 may have a pair of first arms 112 protruding from the support surface 111 and a pair of second arms 119 protruding from the support surface 111. Each first arm 112 may have a second hook element 116 on a free end of the first arm, and each second arm 119 may have a first hook element 115 on a free end of the second arm. The distance between the first hook element 115 and the support surface 111 may be approximately ⅔ of the distance between the second hook element 116 and the support surface 111. The first hook element 115 may be snap-fitted with a second side of an unshown spacer component (reference can be made to the same or similarly configured spacer component 2 as shown in FIGS. 2A and 2B) facing away from the support component 101. In another embodiment not shown, a sunken step may he provided on the second side for each first hook element 115, and the step may be similar to the step 26. When the spacer including the support component 101 is used, it is necessary to provide additional mounting holes in the first member and the second member for the two second arms 119. Similar to the support component 1 shown in FIGS. 1A to 1C, the support component 101 may have a column-shaped body 113, a mounting hole 114, and a recess 117. The embodiment shown in FIGS. 5A and 5B mainly differs from the embodiment shown in FIGS. 1A to 1C in that two pairs of arms are provided, of which one pair of arms is only associated with the first hook elements and the other pair of arms is only associated with the second hook elements, and all the arms are distributed and arranged with an angular separation of 90°. In other aspects, reference may be made to the embodiment shown in FIGS. 1A to 1C.

It will be understood that, the terminology used herein is for the purpose of describing particular aspects only and is not intended to be limiting of the disclosure. As used herein, the singular forms “a”, “an” and “the” are intended to include the plural forms as well, unless the context clearly indicates otherwise. It will be further understood that the terms “comprise” and “include” (and variants thereof), when used in this specification, specify the presence of stated operations, elements, and/or components, but do not preclude the presence or addition of one or more other operations, elements, components, and/or groups thereof. As used herein, the term “and/or” includes any and all combinations of one or more of the associated listed items. Like reference numbers signify like elements throughout the description of the figures.

The thicknesses of elements in the drawings may be exaggerated for the sake of clarity. Further, it will be understood that when an element is referred to as being “on,” “coupled to” or “connected to” another element, the element may be formed directly on, coupled to or connected to the other element, or there may be one or more intervening elements therebetween. In contrast, terms such as “directly on,” “directly coupled to” and “directly connected to,” when used herein, indicate that no intervening elements are present. Other words used to describe the relationship between elements should be interpreted in a like fashion (i.e., “between” versus “directly between”, “attached” versus “directly attached,” “adjacent” versus “directly adjacent”, etc.).

Terms such as “top,” “bottom,” “upper,” “lower,” “above,” “below,” and the like are used herein to describe the relationship of one element, layer or region to another element, layer or region as illustrated in the figures. It will be understood that these terms are intended to encompass different orientations of the device in addition to the orientation depicted in the figures.

It will be understood that, although the terms “first,” “second,” etc. may be used herein to describe various elements, these elements should not be limited by these terms. These tennis are only used to distinguish one element from another. Thus, a first element could be termed a second element without departing from the teachings of the inventive concept.

It will also be appreciated that all example embodiments disclosed herein can be combined in any way.

Finally, it is to be noted that, the above-described embodiments are merely for understanding the present invention but not constitute a limit on the protection scope of the present invention. For those skilled in the art, modifications may be made on the basis of the above-described embodiments, and these modifications do not depart from the protection scope of the present invention.

1. A spacer, configured to space a first member apart from a second member (4), the spacer including:
a support component, which includes a body having a support surface for the first member to engage, the support component further including a first hook element separated from the support surface by a first distance and a second hook element separated from the support surface by a second distance greater than the first distance; and
a spacer component, configured to be placed between the first member and the second member and to space the first member apart from the second member, the spacer component being capable of being snap-fitted with the first hook element or the second hook element relational to the thickness of the first member.

2. The spacer according to claim 1, wherein the support component has a pair of first arms protruding from the support surface, and each first arm has the first hook element and the second hook element.

3. The spacer according to claim 2, wherein each first arm has a first hook element in a center on a width of the first arm and two second hook elements located on a free end of the first arm and on both sides of the first hook element on the width of the first arm.

4. The spacer according to claim 2, wherein the first hook elements on the pair of the first arms face each other and/or the second hook elements on the pair of the first arms face each other.

5. The spacer according to claim 1, wherein the support component has a pair of first arms protruding from the support surface and a pair of second arms protruding from the support surface, each first arm has the second hook element, and each second arm has the first hook element.

6. The spacer according to claim 5, wherein all the arms are distributed and arranged with an angular separation of 90°.

7. The spacer according to claim 5, wherein the second hook elements on the pair of the first arms face each other and/or the first hook elements on the pair of the second arms face each other.

8. The spacer according to claim 1, wherein the spacer component has a protrusion on a first side facing the support component, the support component has a recess for receiving the protrusion, and the protrusion and the recess can prevent the spacer component and the support component from rotating relative to each other during engagement.

9. The spacer according to claim 2, wherein the support component has a recess on an inner side of each first arm in the body of the support component, the spacer component has two protrusions on the first side facing the support component corresponding to each recess, and the protrusions and the recesses can prevent the spacer component and the support component from rotating relative to each other during engagement.

10. The spacer according to claim 1, wherein the spacer component has a sunken step on a second side facing away from the support component, and the step is configured for snap-fit of the spacer component with the first hook element or the second hook element.

11. The spacer according to claim 2, wherein the spacer component has a pair of sunken steps on the second side facing away from the support component, and each step is configured for the snap-fit of the spacer component with the first hook element or the second hook element of one of the first arms.

12. The spacer according to claim 1, wherein the spacer includes a fastening element, the support component and the spacer component have aligned mounting holes, and the mounting holes are configured to receive the fastening element.

13. The spacer according to claim 12, wherein the spacer component has a first projection surrounding the mounting hole of the spacer component on the first side facing the support component, and the first projection is configured to he inserted into a mounting hole of the first member.

14. The spacer according to claim 13, wherein the spacer component has a second projection surrounding the mounting hole of the spacer component on the second side facing away from the support component, and the second projection is configured to be inserted into a mounting hole of the second member.

15. The spacer according to claim 1, wherein the spacer is configured to be used for a base station antenna.

16. The spacer according to claim 15, wherein the spacer is configured to be used for the first member and the second member serving as plate elements of a base station antenna.

17. The spacer according to claim 16, wherein the spacer is configured to be used for the first member and the second member serving as at least one of a reflector, a base plate, and a printed circuit board.

18. A connection system for a base station antenna, including a first member and a second member for a base station antenna, and the spacer according to claim 1, the first member and the second member respectively including at least one mounting hole penetrated by at least one of the support component and the spacer component of the spacer, the first member being put on the support surface of the support component of the spacer, the spacer component of the spacer being placed between the first member and the second member and spacing the first member apart from the second member, and the spacer component being snap-fitted with the first hook element or the second hook element of the support component of the spacer relational to the thickness of the first member.
